(19) United States
(12) Patent Application Publication
(10) Pub. No.: US 2022/0285429 A1
(43) Pub. Date: Sep. 8, 2022

(54) Light-emitting chip and light-emitting unit

(71) Applicant: FOSHAN NATIONSTAR OPTOELECTRONICS CO., LTD., Foshan, Guangdong (CN)

(72) Inventors: Jinhui ZHANG, Foshan, Guangdong (CN); Mengping TAN, Foshan, Guangdong (CN); Yikai YUAN, Foshan, Guangdong (CN); Cheng LI, Foshan, Guangdong (CN)

(21) Appl. No.: 17/637,811

(22) PCT Filed: Apr. 21, 2020
(86) PCT No.: PCT/CN2020/085981

§ 371 Date: Feb. 24, 2022

(30) Foreign Application Priority Data
Aug. 30, 2019 (CN) 201910827017.7

(51) Int. Cl. H01L 27/15

(52) U.S. Cl. CPC H01L 27/156

(57) ABSTRACT

This application provides a light-emitting chip and a light-emitting unit. The light-emitting chip includes light-emitting portions arrayed in n rows and m columns. A surface of the light-emitting chip is provided with n common a-pole electrodes and n×m b-pole electrodes. Each light-emitting portion has an a-pole and a b-pole having an opposite polarity. The b-pole of each light-emitting portion is electrically connected to the b-pole electrode corresponding to the n×m b-pole electrodes, and the a-poles of m light-emitting portions in the i^{th} row are electrically connected to the common a-pole electrode corresponding to the n common a-pole electrodes, where 1≤i≤n, n≥1, m>1, and n, m, and i are integers.

### CROSS-REFERENCE TO RELATED APPLICATION

This application claims the priority to Chinese patent application No. 201910827017.7, entitled “Light-Emitting Chip and Light-Emitting Unit”, filed to the China National Intellectual Property Administration on Aug. 30, 2019, the disclosure of which is hereby incorporated by reference in its entirety.

### TECHNICAL FIELD

This application relates to the field of Light-Emitting Diode (LED) light-emitting chips, and specifically, to a light-emitting chip and a light-emitting unit.

### BACKGROUND

In order to improve the resolution of the display device to decrease the sizes of the light-emitting chips, the requirements for batch transfer of the light-emitting chips are higher. More light-emitting chips need to be packaged in the same area when the light-emitting chip sizes are smaller. However, conventional production processes and apparatuses are hard to efficiently realize related functions.

By taking a 110-inch 4k liquid crystal display television as an example, the quantity of pixels is about 8 million, and each pixel requires 3 light-emitting chips. When 24 million light-emitting chips are bonded by using the convention production process, a die-bonding apparatus is required to operate for at least 20 days. As a result, the production cycle is long, and the production cost is high, which is not conducive to mass production in the factory.

In addition, when the side of the light-emitting chip is smaller, a distance between a positive electrode and a negative electrode of the light-emitting chip becomes smaller, so that processing accuracy requirements for base board circuits and process requirements for die bonding are increased. When the size of a single light-emitting chip is small, since each light-emitting chip has the positive electrode and the negative electrode, each light-emitting chip needs to be independently controlled. When the quantity of light-emitting chips on a single substrate is large, the complexity of base board circuit design increases, resulting in high base board design difficulty.

### SUMMARY

In order to overcome defects of a conventional light-emitting chip, this application provides a light-emitting chip and a light-emitting unit. Light-emitting portions with n rows and m columns are disposed in the light-emitting chip. One of electrodes of light-emitting portion of each line adopts a common electrode structure in the light-emitting chip. Compared with a manner that each light-emitting portion adopts an independent electrode, the quantity of the electrodes of the entire light-emitting chip is decreased. The light-emitting chip has the characteristics of being low in transfer difficulty, low in requirement for base board processing accuracy, low in base board design difficulty, and the like, and has desirable practicability.

Correspondingly, this application provides a light-emitting chip. The light-emitting chip includes light-emitting portions arrayed in n rows and m columns. A surface of the light-emitting chip is provided with n common a-pole electrodes and n×m b-pole electrodes.

Each light-emitting portion has an a-pole and a b-pole having an opposite polarity. The b-pole of each light-emitting portion is electrically connected to the corresponding one of the n×m b-pole electrodes.

The a-poles of m light-emitting portions in the i^{th} row are electrically connected to the corresponding one of the n common a-pole electrodes, where

N≥1, m>1, 1≤i≤n; and

n, m, and i are integers.

In an optional implementation, the n×m b-pole electrodes are arrayed in n rows and m columns on a side of the light-emitting chip. The n common a-pole electrodes are arranged in a straight line on one side of the n×m b-pole electrodes.

In an optional implementation, classification is performed based on light-emitting colors, each of the light-emitting portions includes one or more of a red light-emitting portion, a blue light-emitting portion and a green light-emitting portion.

In an optional implementation, the m light-emitting portions in the i^{th} row have a same light-emitting color.

In an optional implementation, a color conversion portion is disposed on each light-emitting portion.

Classification is performed based on the color of the exit light passing through the color conversion portions, each of the color conversion portions includes one or more of a blue color conversion portion of which exit light is blue, a red color conversion portion of which exit light is red, and a green color conversion portion of which exit light is green.

In an optional implementation, the color conversion portions disposed on the m light-emitting portions in the i^{th} row have a same type; alternatively

the color conversion portions disposed on the n light-emitting portions in the j^{th} column have a same type, where 1≤j≤m, and j is an integer.

In an optional implementation, each of the light-emitting portions includes a substrate, an a-pole layer, a light-emitting layer and a b-pole layer. The a-pole layer is the a-pole of the light-emitting portion. The b-pole layer is the b-pole of the light-emitting portion.

The m light-emitting portions in the i^{th} row have the same substrate. The m light-emitting portions in the i^{th} row have the same a-pole layer. The same a-pole layer is disposed on the same substrate.

The m light-emitting portions in the i^{th} row have m light-emitting layers. The m light-emitting layers are mutually and independently disposed on the same a-pole layer.

The m light-emitting portions in the i^{th} row have m b-pole layers. Any of the m b-pole layers is disposed on the corresponding one of the m light-emitting layers.

In the light-emitting chip, any of the n common a-pole electrodes is electrically connected to the corresponding a-pole layer. Any of the n×m b-pole electrodes is electrically connected to the corresponding b-pole layer.

Correspondingly, this application provides a light-emitting unit. The light-emitting unit includes s light-emitting chips according to any of the above and a base board, where s≥1.

The base board is provided with s×n a-pole pads and s×n×m b-pole pads.

The s×n×m b-pole pads are divided into m groups, a quantity of the b-pole pads in the b-pole pads of the j^{th} group is s×n, and the s×n b-pole pads in the b-pole pads of the i^{th} group are electrically connected to each other, where 1≤j≤m, j is an integer.

The s light-emitting chips are disposed on the base board, and have s×n common a-pole electrodes and s×n×m b-pole electrodes in total.

Any of the s×n common a-pole electrodes is electrically connected to the corresponding one of the s×n a-pole pads. Any of the s×n×m b-pole electrodes is electrically connected to the corresponding one of the s×n×m b-pole pads.

In an optional implementation, m common b-pole connection points and s×n a-pole connection points are disposed on the base board.

The s×n of the b-pole pads of the j^{th} group are electrically connected to the corresponding one of them common b-pole connection points.

The s×n a-pole pads are respectively and electrically connected to the corresponding one of the s×n a-pole connection points.

In an optional implementation, the n common a-pole electrodes and n×m b-pole electrodes of any of the s light-emitting chips are disposed on a side of the light-emitting chip.

Arrangement positions of the s×n a-pole pads on the base board respectively correspond to arrangement positions of the s×n common a-pole electrodes.

Arrangement positions of the s×n×m b-pole pads on the base board respectively correspond to arrangement positions of the s×n×m b-pole electrodes.

This application provides a light-emitting chip. Light-emitting portions with n rows and m columns are disposed in the light-emitting chip. One of electrodes of each light-emitting portion adopts a common electrode structure in the light-emitting chip. Compared with a manner that each light-emitting portion adopts an independent electrode, the quantity of the electrodes of the entire light-emitting chip is decreased. The light-emitting unit has the characteristics of being less in wiring, low in layout difficulty, low in transfer difficulty, low in requirement for base board processing accuracy and the like, and has desirable practicability. Correspondingly, this application further provides a light-emitting unit. One of electrodes of every n light-emitting portions in the light-emitting chip adopts a common electrode structure on a base board. Therefore, the quantity of connection points for external electrical connection of the entire light-emitting unit is further decreased, so that the light-emitting unit has desirable practicability.

### BRIEF DESCRIPTION OF THE DRAWINGS

In order to more clearly illustrate the embodiments of this application or the technical solutions in the prior art, the drawings used in the description of the embodiments or the prior art will be briefly described below. It is apparent that the drawings in the following descriptions are merely some embodiments of this application. Other drawings can be obtained from those skilled in the art according to these drawings without any creative work.

FIG. 1 shows a schematic structural diagram of a light-emitting chip according to Embodiment I of this application.

FIG. 2 shows a schematic diagram of a circuit electrical connection structure of the light-emitting chip according to Embodiment I of this application.

FIG. 3 shows a schematic structural diagram of a light-emitting chip according to Embodiment III of this application.

FIG. 4 shows a partial schematic structural enlarged view of a light-emitting chip according to Embodiment IV of this application.

FIG. 5 shows a schematic diagram of a cross-sectional structure of a light-emitting chip according to Embodiment VI of this application.

FIG. 6 shows a schematic diagram of a cross-sectional structure of a light-emitting chip matrix according to Embodiment VI of this application.

FIG. 7 shows a schematic structural diagram of a light-emitting chip matrix processed via step S102 and step S103 according to Embodiment VI of this application.

FIG. 8 shows a schematic structural diagram of a light-emitting chip matrix processed with a common a-pole electrode according to Embodiment VI of this application.

FIG. 9 shows a schematic diagram of a circuit structure of a light-emitting unit according to Embodiment VIII of this application.

FIG. 10 shows a schematic structural diagram of the light-emitting unit according to Embodiment VIII of this application.

FIG. 11 shows a schematic structural diagram of a light-emitting unit according to Embodiment IX of this application.

### DETAILED DESCRIPTION OF THE EMBODIMENTS

The technical solutions in the embodiments of this application will be clearly and completely described below in combination with the drawings in the embodiments of this application. It is apparent that the described embodiments are only part of the embodiments of this application, not all the embodiments. All other embodiments obtained by those of ordinary skill in the art on the basis of the embodiments in this application without creative work fall within the scope of protection of this application.

### Embodiment I

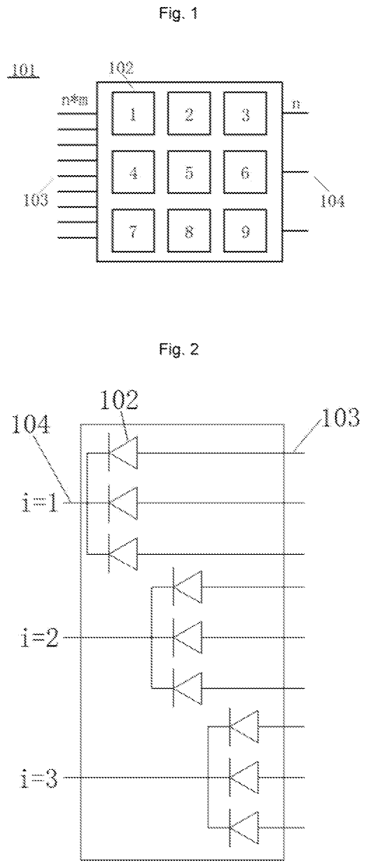

FIG. 1 shows a schematic structural diagram of a light-emitting chip according to an embodiment of this application. FIG. 2 shows a schematic diagram of a circuit electrical connection structure of the light-emitting chip according to an embodiment of this application. It needs to be noted that, the schematic structural diagram of the light-emitting chip as shown in FIG. 1 is merely used for showing the quantity of the electrodes. In a specific implementation, arrangement positions of the electrodes may be designed according to requirements. The schematic diagram of a circuit electrical connection structure of the light-emitting chip as shown in FIG. 2 is merely used for schematically showing the quantity of the light-emitting portions. In a specific implementation, an arrangement positions of the light-emitting chip may be designed according to requirements.

An embodiment of this application provides a light-emitting chip 101. A plurality of light-emitting portions 102 are arrayed in the light-emitting chip 101. The plurality of light-emitting portions 102 are arranged in n rows and m columns. A surface of the light-emitting chip is provided with n common a-pole electrodes 104 and n×m b-pole electrodes 103.

Each of the light-emitting portions 102 arranged in n rows and m columns has an a-pole and a b-pole having opposite polarity. The b-pole of each light-emitting portion 102 is electrically connected to the corresponding one of the n×m b-pole electrodes 103. The a-poles of all of the light-emitting portions 102 (m light-emitting portions 102 in the i^{th} row) in the i^{th} row are electrically connected to the i^{th} common a-pole electrode 104 of the light-emitting chip, where

1≤i≤n and m>1; and n, m, and i are integers.

Specifically, in this embodiment of this application, the light-emitting chip 101 including three rows and three columns of the light-emitting portions is taken as an example for description, that is, n=3, and m=3. In this embodiment of this application, the a-poles being negative electrodes and the b-poles being positive electrodes are taken as an example for description. Correspondingly, the common a-pole electrodes are common negative electrodes, and the b-pole electrodes are positive electrodes.

With reference to the schematic structural diagram of the light-emitting chip as shown in FIG. 1 and the schematic diagram of a circuit structure of the light-emitting chip as shown in FIG. 2, nine positive electrodes 103 and three common negative electrodes 104 are disposed on the surface of the light-emitting chip 101. In the light-emitting chip 101, the nine light-emitting portions 102 are arrayed in three rows and three columns. The negative electrodes of the three light-emitting portions 102 in each row are electrically connected to the corresponding common negative electrode 104. The positive electrode of each light-emitting portion 102 is electrically connected to the positive electrode 103. Specifically, the negative electrodes of the light-emitting portions 102 in each row are electrically connected to the corresponding common negative electrode after electrical connection.

On the one hand, according to the light-emitting chip in this embodiment of this application, the plurality of light-emitting portions are integrated into one light-emitting chip, so that a size of the light-emitting chip can be increased, and a transfer difficulty of the light-emitting portions can be reduced. On the other hand, through the design of the common negative electrodes of each row of the light-emitting portions, compared with an implementation that two electrodes of each light-emitting portion are electrically connected independently, under a same quantity scale of the light-emitting portions, the quantity of the overall required electrodes can be decreased, and circuit design difficulty of a base board and processing accuracy requirements can be reduced.

### Embodiment II

Specifically, the n rows and m columns of the light-emitting portions may be single color light-emitting portions, or may further be light-emitting portions adopting different light-emitting types. In a specific implementation, in view of an application occasion required for the light-emitting chip and a light-emitting mode of the light-emitting chip, design is performed.

In view of the application occasion of the light-emitting chip, the light-emitting chip may adopt the light-emitting portions having a same light-emitting color, so that the light-emitting chip is applicable to products requiring uniform light-emitting colors, such as a backlight module. Alternatively, the light-emitting chip may adopt the light-emitting portions having different light-emitting colors. By controlling the colors of the light-emitting portions having different light-emitting colors, colorful display of the light-emitting chip is realized, so that the light-emitting chip is applicable to products requiring a plurality of light-emitting colors, such as a color development module.

For different light-emitting modes of the light-emitting chip, a basic structure of the light-emitting chip has a certain difference. If light emitted by the light-emitting portions in the light-emitting chip may directly pass through the light-emitting chip for color development, the light-emitting color of the light-emitting portions is determined by a color required by the light-emitting chip. Alternatively, after color conversion is performed in the light emitted by the light-emitting portions in the light-emitting chip by means of a color conversion portion, the light is then emitted from the light-emitting chip, so that the light-emitting portions may adopt the single color light-emitting portions. By disposing the color conversion portions having different color conversion types to process the light emitted by the single color light-emitting portions, the colorful display of the light-emitting chip is realized.

### Embodiment III

Optionally, color classification is performed based on exit light passing through the color conversion portions, each of the color conversion portions includes one or more of a blue color conversion portion of which exit light is blue, a red color conversion portion of which exit light is red, and a green color conversion portion of which exit light is green.

For colorful devices such as display screen devices, during a specific implementation, each light-emitting chip may be used as a light-emitting pixel for use. In order to realize the full-color of the light-emitting pixels, in this embodiment of this application, the quantity of the n rows and m columns of the light-emitting portions is greater than or equal to three. Classification is performed based on light-emitting colors, the n rows and m columns of the light-emitting portions include red light-emitting portions, blue light-emitting portions and green light-emitting portions.

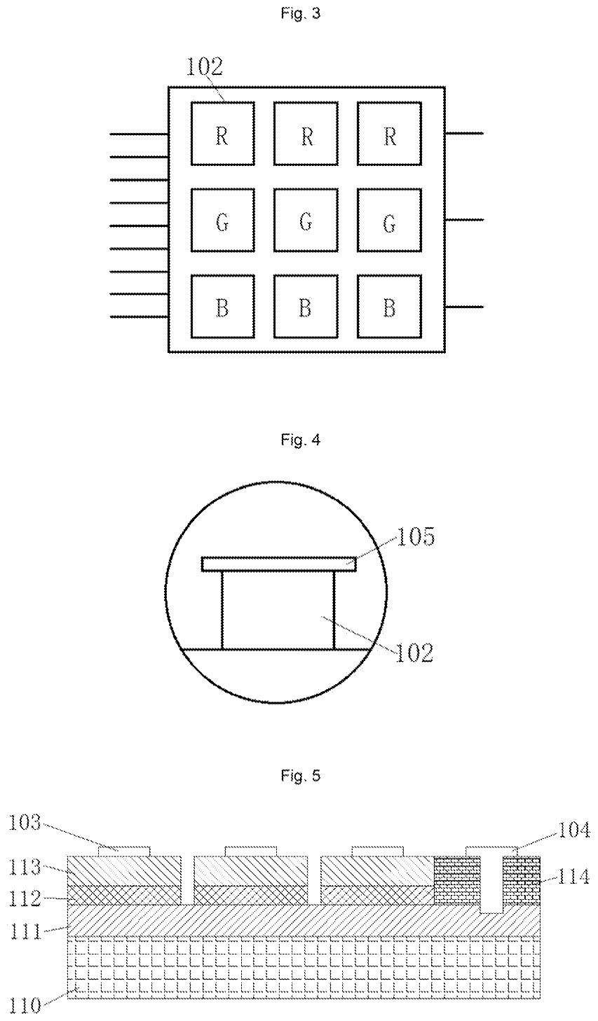

FIG. 3 shows a schematic structural diagram of a light-emitting chip according to an embodiment of this application. On the basis of Embodiment I, the full color of the light-emitting chip can be realized by designing light-emitting types of the light-emitting portions of the light-emitting chip.

Optionally, the light-emitting portions 102 in each row in the light-emitting chip have a same light-emitting color.

Specifically, in this embodiment of this application, the light-emitting portions 102 in the first row are red light-emitting portions (R), the light-emitting portions 102 in the second row are green light-emitting portions (G), and the light-emitting portions 102 in the third row are blue light-emitting portions (B). In the single light-emitting chip, through the adoption of the light-emitting portions 102 with three different light-emitting colors, the full color display of the light-emitting chip can be realized, so that the invention has desirable practicability.

Optionally, the light-emitting portions 102 in each row in the light-emitting chip have different light-emitting colors.

Specifically, in this embodiment of this application, the m light-emitting portions in the i^{th} row are classified based on the light-emitting colors. The light-emitting portions include the red light-emitting portions, the blue light-emitting portions and the green light-emitting portions.

### Embodiment IV

In addition to implementations in Embodiment III, there are various implementations for realizing the full color display of the light-emitting chip. This application further provides a light-emitting chip structure for realizing the full color display of a light-emitting chip.

Specifically, FIG. 4 shows a partial schematic structural enlarged view of a light-emitting chip according to an embodiment of this application. For the color development of the light-emitting chip, a color development effect of the light-emitting chip in this embodiment of this application is similar to a color development effect of the light-emitting chip in Embodiment Ill.

Specifically, in this embodiment of this application, all of the light-emitting portions 102 have the same light-emitting color, or may have different light-emitting colors. Optionally, light emitted by the light-emitting portions 102 may be the light with the same color, such as blue light and ultraviolet light. It is to be noted that, due to a subtle difference between different light-emitting portion structures and materials, specific light-emitting light wavelengths and light-emitting colors of the light-emitting portions may have subtle differences. Therefore, the light with the same light-emitting color according to this embodiment of this application refers to light within a certain wavelength range, not the light with an identical light-emitting light wavelength and an identical light-emitting light color. By disposing color conversion portions 105 on the light-emitting portions 102, color conversion is performed on the light emitted by the light-emitting portions 102 by means of the color conversion portions 105, so that single color light is converted into exit light with required color and then emitted, so as to realize the full color display of the light-emitting chip.

Optionally, color classification is performed based on exit light passing through the color conversion portions, each of the color conversion portions includes one or more of a blue color conversion portion of which exit light is blue, a red color conversion portion of which exit light is red, and a green color conversion portion of which exit light is green. Generally, the red color conversion portions and the green color conversion portions are respectively made of corresponding fluorescent conversion materials. Structures of the blue color conversion portions are determined according to the light-emitting colors of the light-emitting portions. When the light-emitting portions 102 are the blue light-emitting portions, the blue color conversion portions may adopt empty window structures or transparent packaging colloid. Light emitted by the blue light-emitting portions may directly penetrated. When the light-emitting portions 102 are purple light-emitting portions, the blue color conversion portions may be make of a corresponding fluorescent conversion material.

It is to be noted that, structures of the color conversion portions have various implementations. Optionally, structures as shown in the drawings may be adopted. The color conversion portions cover top surfaces of the light-emitting portions 102; alternatively, the color conversion portions may cover all of surfaces of the light-emitting portions 102. Since the arrangement structures of the color conversion portions are various, descriptions are not described in details in the embodiments of this application.

In view of a color development manner of the light-emitting portions in the light-emitting chip as shown in FIG. 3, optionally, in the light-emitting chip, the color conversion portions 105 adopted by each row of the light-emitting portions 102 have the same color conversion type. That is to say, the color conversion portions 105 adopted by the m light-emitting portions 102 in the i^{th} row have the same color conversion type. Alternatively and optionally, in the light-emitting chip, the color conversion portions 105 adopted by each column of the light-emitting portions 102 have the same color conversion type. That is to say, the color conversion portions 105 adopted by the n light-emitting portions 102 in the j^{th} column have the same color conversion type.

### Embodiment V

Specifically, in view of the light-emitting chip structure in Embodiment III and Embodiment IV, during a specific implementation, the light-emitting chip may be divided into a plurality of sub light-emitting chips. Therefore, the required light-emitting chip is formed by using the plurality of sub light-emitting chips.

Specifically, the light-emitting portions in the same row or the same column and having the same color are integrated into one sub light-emitting chip. Through the arrangement manner, each of the sub light-emitting chips has the same light-emitting color, and each sub light-emitting chip is in an independent structure. Therefore, regardless of whether the light-emitting mode in Embodiment III and Embodiment IV is adopted, each light-emitting portion in each sub light-emitting chip may have the same structure. In this way, the sub light-emitting chips can be more convenient in processing, and have desirable processing convenience.

### Embodiment VI

Specifically, in view of the light-emitting chip introduced in Embodiment I to Embodiment V, an embodiment of this application provides a specific structure for a light-emitting chip.

Basically, the light-emitting chip according to this embodiment of this application includes n rows and m columns of light-emitting portions. Each of the light-emitting portions includes a substrate, an a-pole layer, a light-emitting layer and a b-pole layer. The a-pole layer is an a-pole of the light-emitting portion. The b-pole layer is a b-pole of the light-emitting portion.

The m light-emitting portions in the i^{th} row have the same substrate. The m light-emitting portions in the i^{th} row have the same a-pole layer. The same a-pole layer is disposed on the same substrate.

The m light-emitting portions in the i^{th} row have m light-emitting layers. The m light-emitting layers are mutually and independently disposed on the same a-pole layer.

The m light-emitting portions in the i^{th} row have m b-pole layers. Any of the m b-pole layers is disposed on the corresponding one of the m light-emitting layers.

In the light-emitting chip, any of the n common a-pole electrodes is electrically connected to the corresponding a-pole layer. Any of the n×m b-pole electrodes is electrically connected to the corresponding b-pole layer.

FIG. 5 shows a schematic diagram of a cross-sectional structure of a light-emitting chip according to an embodiment of this application. In view of the entire light-emitting chip, a lowest layer of the light-emitting chip according to this embodiment of this application is provided with the substrate 110 commonly used by all of the light-emitting portions. The n a-pole layers 111 independent to each other are disposed on the substrate 110. The m light-emitting layers 112 independent to each other are disposed on each a-pole layer 111. The corresponding b-pole layer 113 is disposed on each light-emitting layer 112. Each b-pole layer 113 is provided with the corresponding b-pole electrode 103. Each b-pole electrode 103 is electrically connected to the corresponding b-pole layer 113. Correspondingly, each a-pole layer 111 is electrically connected to the corresponding common a-pole electrode 104. During a specific implementation, optionally, a passivation layer 114 may be used to support the common a-pole electrode 104 and protect the a-pole layer 111, so that the common a-pole electrode 104 and a top surface of the b-pole electrode may be at a same height, to achieve external connection.

It is to be noted that, the schematic structural diagram shown in FIG. 5 is one of cross sections of the light-emitting chip, so that it schematically shows cross sectional structures of one row of the light-emitting chips. The a-pole layers 111 among different rows of the light-emitting portions are insulated from each other.

Specifically, in view of the light-emitting chip in this embodiment of this application, an embodiment of this application further provides a method for manufacturing a light-emitting chip. The method for manufacturing a light-emitting chip includes the following steps.

At S101, a light-emitting chip matrix is manufactured.

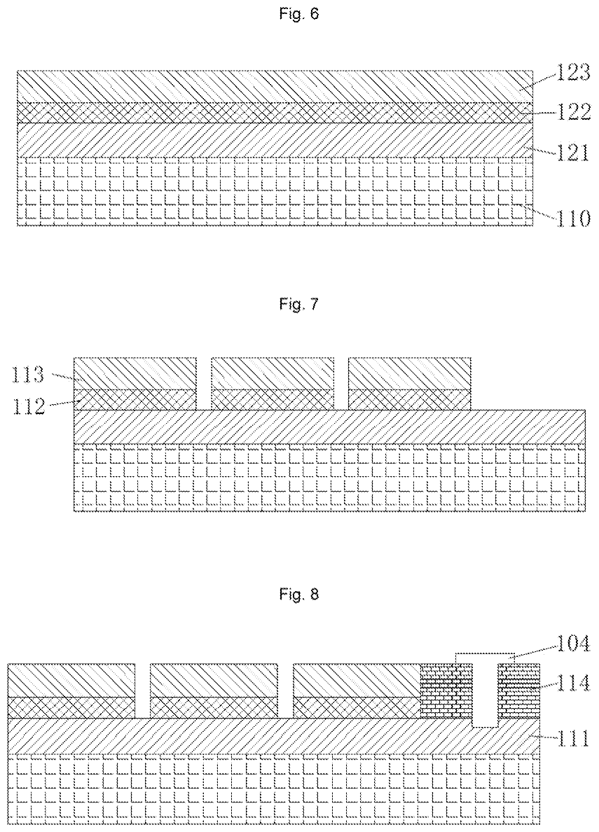

FIG. 6 shows a schematic diagram of a cross-sectional structure of a light-emitting chip matrix. The light-emitting chip matrix includes a substrate 110, an a-pole material layer 121, a light-emitting material layer 122, and a b-pole material layer 123 that are successively laminated.

At S102, the b-pole material layer 123 is divided into n rows and m columns of b-pole layers 113.

At S103, the light-emitting material layer 122 is divided into n rows and m columns of light-emitting layers 112.

FIG. 7 shows a schematic structural diagram of a light-emitting chip matrix processed via step S102 and step S103. During a specific implementation, an etching method is usually used. According to a size of a light-emitting portion, the b-pole material layer 123 and the light-emitting material layer 122 are divided into n rows and m columns, so as to form the light-emitting layers 112 and the b-pole layers 113 of the light-emitting portion.

At S104, a common a-pole electrode is manufactured.

For ease of welding, a positive pin and a negative pin of a flip-chip device are required to be disposed on a same side of the light-emitting chip. After the light-emitting chip matrix is processed via steps S102 and S103, a structure of a light-emitting portion device is formed. An electrode of the light-emitting portion is required to be electrically connected to an electrode of the light-emitting chip, to complete the formation of the light-emitting chip.

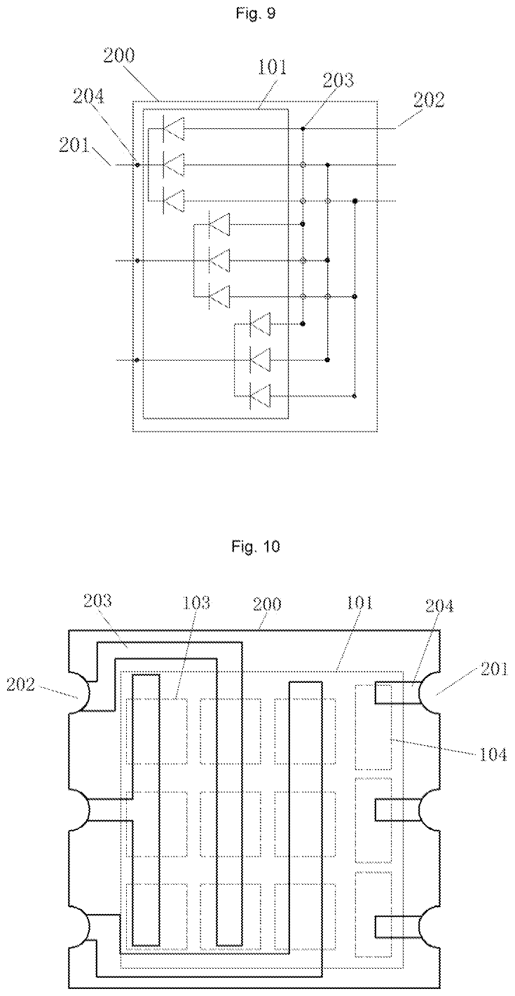

FIG. 8 shows a schematic structural diagram of a light-emitting chip matrix processed with a common a-pole electrode. Optionally, a preset position of the a-pole material layer 121 is first etched by means of MESA (a bench cut method) to obtain the required a-pole layers 111. Then, a passivation layer 114 is disposed in a corresponding position. The passivation layer 114 may protect the a-pole layers 111. Generally, a height of the passivation layer 114 is the same as heights of the b-pole layers 113. Then, a common a-pole electrode 104 is electrically connected to the a-pole layers 111 through the passivation layer 114 or through a through hole in the passivation layer 114. Finally, the common a-pole electrode 104 is disposed on a top surface of the passivation layer 114. The common a-pole electrode 104 passes through the passivation layer 114 to achieve an electrical connection with the a-pole layers 111.

At S105, a b-pole electrode is manufactured.

With reference to the schematic diagram of a cross-sectional structure of the light-emitting chip shown in FIG. 5, the entire light-emitting chip in this embodiment of this application is processed by respectively manufacturing the b-pole electrodes 103 electrically connected to the b-pole layers 113 on top surfaces of the b-pole layers 113. It is to be noted that, the schematic diagram of the cross-sectional structure of the light-emitting chip shown in FIG. 5 is only one of schematic structures. Positions and quantities of the b-pole electrodes and the common a-pole electrodes can be adjusted according to actual situations.

Compared with a conventional process for processing a flip-chip light-emitting chip, the light-emitting chip introduced in this embodiment of this application does not greatly change a manufacturing process. Common a-pole arrangement structures of a plurality of light-emitting portions in the light-emitting chip can be realized by dividing the b-pole material layer and the light-emitting material layer and reserving an implementation of the a-pole material layer. Therefore, the light-emitting chip is high in production efficiency and has desirable practicability.

### Embodiment VII

Optionally, for ease of the welding of the light-emitting chip, during a specific implementation, the n×m b-pole electrodes in the light-emitting chip are arrayed in n rows and m columns on a side of the light-emitting chip. The n common a-pole electrodes are arranged in a straight line on one side of the n×m b-pole electrodes.

In order to further reduce a quantity of wiring, this application further provides a light-emitting unit. Basically, the light-emitting unit includes s light-emitting chips according to any of the above and a base board, where s≥1.

The base board is provided with s×n a-pole pads and s×n×m b-pole pads.

The s×n×m b-pole pads are divided into m groups, a quantity of the b-pole pads in the b-pole pads of the j^{th} group is s×n, and the s×n b-pole pads in the b-pole pads of the j^{th} group are electrically connected to each other, where 1≤j≤m, and j is an integer.

The s light-emitting chips are disposed on the base board, and have s×n common a-pole electrodes and s×n×m b-pole electrodes in total.

Any of the s×n common a-pole electrodes is electrically connected to the corresponding one of the s×n a-pole pads. Any of the s×n×m b-pole electrodes is electrically connected to the corresponding one of the s×n×m b-pole pads.

Optionally, m common b-pole connection points and s×n a-pole connection points are disposed on the base board.

The s×n b-pole pads in the j^{th} group are electrically connected to the corresponding one of the m common b-pole connection points.

The s×n a-pole pads are respectively and electrically connected to the corresponding one of the s×n a-pole pads.

Optionally, the n common a-pole electrodes and n×m b-pole electrodes of any of the s light-emitting chips are disposed on a side of the light-emitting chip.

Arrangement positions of the s×n a-pole pads on the base board respectively correspond to arrangement positions of the s×n common a-pole electrodes.

Arrangement positions of the s×n×m b-pole pads on the base board respectively correspond to arrangement positions of the s×n×m b-pole electrodes.

The light-emitting unit provided in this application is described below through Embodiment VIII and Embodiment IX.

### Embodiment VIII

FIG. 9 shows a schematic diagram of a circuit structure of a light-emitting unit according to an embodiment of this application. Further, in order to further reduce a quantity of wiring, this embodiment of this application further provides a light-emitting unit structure. Based on any of the above embodiments, the light-emitting unit further includes a base board 200. That is to say, the light-emitting unit according to this embodiment of this application includes a light-emitting chip 101 and the base board 200, where s=1.

Since the base board 200 is required to be designed corresponding to a light-emitting chip structure, in FIG. 9, the light-emitting chip structure corresponding to the light-emitting chip including three rows and three columns of light-emitting portions is used as an example for description.

The base board 200 is provided with n a-pole pads 204 and n×m b-pole pads 203. The n×m b-pole pads 203 are divided into m groups, a quantity of the b-pole pads in the b-pole pads of the j^{th} group is n, and all of the b-pole pads in the b-pole pads of the j^{th} group are electrically connected to each other, where 0<j≤m, and j is an integer. Optionally, the base board 200 in this embodiment of this application is further provided with n a-pole connection points 201 and m common b-pole connection points 202.

Optionally, in this embodiment of this application, n a-pole pads 204 are respectively and electrically connected to the n a-pole connection points 201.

Optionally, in this embodiment of this application, all of the b-pole pads in the b-pole pads in the j^{th} group are respectively and electrically connected to the common b-pole connection points 202.

The light-emitting chip 101 is disposed on the base board 200. The n a-pole electrodes are respectively and electrically connected to the n a-pole pads 204. The n×m b-pole electrodes are respectively and electrically connected to n×m b-pole pads 203.

Optionally, for ease of external wiring, or for ease of the designing of an external circuit, the a-pole connection points 201 and the common b-pole connection points 202 may be disposed on edges of the base board 200. Further, the a-pole connection points 201 and the common b-pole connection points 202 are respectively disposed on two side edges of the base board 200.

FIG. 10 shows a schematic structural diagram of the light-emitting unit according to an embodiment of this application. Optionally, referring to the light-emitting chip structure introduced in Embodiment VI, the n common a-pole electrodes and n×m b-pole electrodes of the light-emitting chip are disposed on one side of the light-emitting chip. Arrangement positions of the n a-pole pads on the base board 200 correspond to arrangement positions of the n common a-pole electrodes. Arrangement positions of the n×m b-pole pads on the base board 200 respectively correspond to arrangement positions of the n×m b-pole electrodes.

Specifically, in order to simultaneously showing structures of the light-emitting chip and the base board 200, in FIG. 10, a heavy line profile is the structure of the base board 200. A fine line profile is a bottom structure of the light-emitting chip. Dotted line profiles are structures of the b-pole electrodes and the common a-pole electrodes on the light-emitting chip. One side of the light-emitting chip 101 in this embodiment of this application is provided with the b-pole electrodes 103 arrayed in three rows and three columns and three common a-pole electrodes 104 arranged in a straight line and disposed on one side of the b-pole electrodes. Correspondingly, the base board 200 in this embodiment of this application is correspondingly provided with three rows and three columns of the b-pole pads 203 and three a-pole pads 204 arranged in a straight line. The three a-pole pads 204 are electrically connected to the three a-pole connection points 201. Since the b-pole pads 203 in the same column are electrically connected to one of the common b-pole connection points 202, the b-pole pads 203 in the same column according to this embodiment of this application adopt an integrated structure.

Specifically, the light-emitting chip is disposed on the base board 200. The b-pole electrodes 103 in the same column are electrically connected to one of the common b-pole connection points 202 on the base board 200 by means of the base board 200. Each of the common a-pole electrodes 104 is electrically connected to one of the a-pole connection points 201 on the base board 200 by means of the base board 200.

Through the implementation structure in this embodiment of this application, the quantity of the connection points of the entire light-emitting unit for external electrical connection is further reduced to n+m. In this way, wiring quantities or layout difficulties during specific implementation can be simplified. Therefore, the light-emitting unit has desirable practicability.

### Embodiment IX

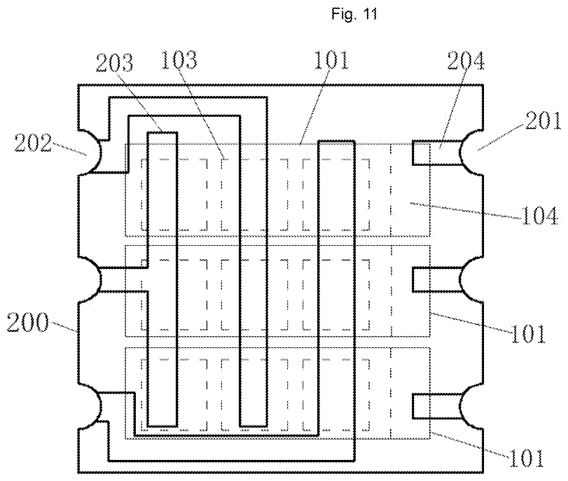

FIG. 11 shows a schematic structural diagram of a light-emitting unit according to Embodiment IX of this application. A heavy line profile is the structure of the base board 200. A fine line profile is a bottom structure of the light-emitting chip. Dotted line profiles are structures of the b-pole electrodes and the common a-pole electrodes on the light-emitting chip.

The light-emitting unit in this embodiment of this application includes three light-emitting chips 101 and a base board 200, that is, s=3. The three light-emitting chips 101 are arranged in three rows. Each light-emitting chip 101 is provided with three light-emitting portions. The three light-emitting portions are arranged in one row and three columns. Correspondingly, a bottom surface of each light-emitting chip 101 is provided with three b-pole electrodes 103 and one common a-pole electrode 104.

Correspondingly, the base board 200 is provided with nine b-pole pads 203. The nine b-pole pads 203 are arranged in three rows and three columns. The three b-pole pads 203 in each column are electrically connected to each other. The base board 200 is further provided with three a-pole pads 104. Three a-pole connection points 201 and three common b-pole connection points 202 are respectively disposed on two side of the base board 200. Each a-pole connection point 201 is correspondingly and electrically connected to one of the a-pole pads 104. Each common b-pole connection point 202 is correspondingly and electrically connected to one column of the three b-pole pads 203.

Optionally, the light-emitting portions in each row have a same light-emitting color.

The light-emitting portions in each row in the light-emitting unit according to this embodiment of this application are formed by respectively adopting independent light-emitting chips. When the light-emitting portions in each row in the light-emitting unit adopt the same color, since structures of the light-emitting portions are consistent, through the implementations of this embodiment of this application, a production difficulty of the light-emitting chips can be reduced, thereby reducing a production cost.

To sum up, the embodiments of this application provide a light-emitting chip. Light-emitting portions with n rows and m columns are disposed in the light-emitting chip. One of electrodes of each light-emitting portion adopts a common electrode structure in the light-emitting chip. Compared with a manner that each light-emitting portion adopts an independent electrode, the quantity of pins of the entire light-emitting chip is decreased. The light-emitting unit has the characteristics of being less in wiring, low in layout difficulty, low in transfer difficulty, low in requirement for base board processing accuracy and the like, and has desirable practicability. Correspondingly, this application further provides a light-emitting unit. Another electrode of every n light-emitting portions in the light-emitting chip adopts a common electrode structure on a base board. Therefore, the quantity of connection points for external electrical connection of the entire light-emitting unit is further decreased, so that the light-emitting unit has desirable practicability.

The light-emitting chip and the light-emitting unit provided in the embodiments of this application are described in detail above. Detailed examples are used in this specification to describe the principles and implementations of this application. The description of the above embodiments is merely used to facilitate understanding of the method and the core idea of this application. In addition, for those of ordinary skill in the art, according to the idea of this application, there will be changes in the specific implementations and the scope of application. In summary, the content of this specification should not be construed as a limitation of this application.

1. A light-emitting chip, comprising light-emitting portions arrayed in n rows and m columns, wherein a surface of the light-emitting chip is provided with n common a-pole electrodes and n×m b-pole electrodes;
wherein each light-emitting portion is provided with an a-pole and a b-pole of which polarities are opposite, and the b-pole of each light-emitting portion is electrically connected to one corresponding b-pole of the n×m b-pole electrodes; and
the a-poles of m light-emitting portions in the i^{th} row are electrically connected to the corresponding one of the n common a-pole electrodes, wherein
n≥1, m>1, 1≤i≤n; and
n, m, and i are integers.

2. The light-emitting chip according to claim 1, wherein the n×m b-pole electrodes are arrayed in n rows and m columns on a side of the light-emitting chip, and the n common a-pole electrodes are arranged in a straight line on one side of the n×m b-pole electrodes.

3. The light-emitting chip according to claim 1, wherein each of the light-emitting portions comprises at least a red light-emitting portion, a blue light-emitting portion and a green light-emitting portion, wherein the classification of the light-emitting portions is based on light-emitting color.

4. The light-emitting chip according to claim 1, wherein the m light-emitting portions in the i^{th} row have a same light-emitting color.

5. The light-emitting chip according to claim 1, wherein a color conversion portion is set on each light-emitting portion, and the color conversion portion is classified based on the color of exit light passing through the color conversion portions; and
each of the color conversion portions comprises at least a blue color conversion portion of which exit light is blue, a red color conversion portion of which exit light is red, and a green color conversion portion of which exit light is green.

6. The light-emitting chip according to claim 5, wherein the color conversion portions set on the m light-emitting portions in the i^{th} row have a same type.

7. The light-emitting chip according to claim 1, wherein each of the light-emitting portions comprises a substrate, an a-pole layer, a light-emitting layer and a b-pole layer, the a-pole layer is the a-pole of the light-emitting portion, and the b-pole layer is the b-pole of the light-emitting portion;
the m light-emitting portions in the i^{th} row have the same substrate, the m light-emitting portions in the i^{th} row have the same a-pole layer, and the same a-pole layer is disposed on the same substrate;
the m light-emitting portions in the i^{th} row have m light-emitting layers, and the m light-emitting layers are mutually and independently disposed on the same a-pole layer;
the m light-emitting portions in the i^{th} row have m b-pole layers, and any of the m b-pole layers is disposed on the corresponding one of the m light-emitting layers; and
in the light-emitting chip, any of the n common a-pole electrodes is electrically connected to the corresponding a-pole layer, and any of the n×m b-pole electrodes is electrically connected to the corresponding b-pole layer.

8. A light-emitting unit, comprising s light-emitting chips according to claim 1 and a base board, wherein s≥1;
the base board is set with s×n a-pole pads and s×n×m b-pole pads;
the s×n×m b-pole pads are divided into m groups, a quantity of the b-pole pads in the b-pole pads of the j^{th} group is s×n, and the s×n b-pole pads in the b-pole pads of the j^{th} group are electrically connected to each other, wherein 1≤j≤m, j is an integer;
the s light-emitting chips are disposed on the base board, and have s×n common a-pole electrodes and s×n×m b-pole electrodes in total; and
any of the s×n common a-pole electrodes are electrically connected to the corresponding one of the s×n a-pole pads, and any of the s×n×m b-pole electrodes are electrically connected to the corresponding one of the s×n×m b-pole pads.

9. The light-emitting unit according to claim 8, wherein m common b-pole connection points and s×n a-pole connection points are set on the base board;
the s×n b-pole pads in the b-pole pads of the j^{th} group are electrically connected to the corresponding one of the m common b-pole connection points; and
the s×n a-pole pads are respectively and electrically connected to the corresponding one of the s×n a-pole connection points.

10. The light-emitting unit according to claim 8, wherein the n common a-pole electrodes and n×m b-pole electrodes of any of the s light-emitting chips are set on a side of the light-emitting chip;
arrangement positions of the s×n a-pole pads on the base board respectively correspond to arrangement positions of the s×n common a-pole electrodes; and
arrangement positions of the s×n×m b-pole pads on the base board respectively correspond to arrangement positions of the s×n×m b-pole electrodes.

11. The light-emitting chip according to claim 3, wherein the m light-emitting portions in the i^{th} row have a same light-emitting color.

12. The light-emitting chip according to claim 5, wherein the color conversion portions set on the n light-emitting portions in the j^{th} column have a same type, wherein 1≤j≤m, and j is an integer.

13. The light-emitting chip according to claim 1, wherein a negative electrodes of the light-emitting portions in each row are electrically connected to the corresponding common negative electrode after electrical connection.

14. The light-emitting chip according to claim 1, wherein the quantity of the n rows and m columns of the light-emitting portions is greater than or equal to three.

15. The light-emitting chip according to claim 1, wherein the light-emitting chip is formed by using a plurality of sub light-emitting chips.

16. The light-emitting chip according to claim 15, wherein the light-emitting portions in the same row or the same column and having the same color are integrated into one sub light-emitting chip.

17. The light-emitting chip according to claim 15, wherein each light-emitting portion in each sub light-emitting chip have the same structure.

18. The light-emitting unit according to claim 9, wherein the a-pole connection points and the common b-pole connection points is set on edges of the base board.

19. The light-emitting unit according to claim 18, wherein the a-pole connection points and the common b-pole connection points are respectively set on two side edges of the base board.

20. The light-emitting unit according to claim 8, wherein the light-emitting portions in each row have a same light-emitting color.
